(19) United States
(12) Patent Application Publication
(10) Pub. No.: US 2008/0052660 A1
(43) Pub. Date: Feb. 28, 2008

(54) METHOD OF CORRECTING A DESIGNED PATTERN OF A MASK

(75) Inventors: Woo-seok SHIM, Seoul (KR); Moon-Hyun YOO, Suwon-si (KR); Chun-Suk SUH, Yongin-si (KR); Jung-Hyeon LEE, Yongin-si (KR); Ji-Suk HONG, Hwaseong-si (KR); Yong-Hee PARK, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/830,265

(22) Filed: Jul. 30, 2007

(30) Foreign Application Priority Data
Jul. 31, 2006 (KR) 2006-71901

(51) Int. Cl. G03F 1/00; G06F 17/50

(52) U.S. Cl. 716/19

(57) ABSTRACT

A method of correcting a design pattern of a mask takes into account the overlay margin between adjacent one of actual patterns that are stacked on a substrate. First, a pattern of a photomask for forming a first one of the actual patterns on a substrate is conceived. Also, information representing the image of a second one of the actual patterns is produced. Then, optical proximity correction (OPC) is performed on the first pattern based on the information. The information may be obtained by simulating the transcription of a photomask having a second pattern designed to form the second actual pattern, or by forming the second actual pattern and then capturing the image of the second actual pattern. Accordingly, a sufficient margin is provided between the second actual pattern and the first pattern on which the optical proximity correction has been performed.

### CROSS-REFERENCE TO RELATED APPLICATION

This application claims priority under 35 USC §119 to Korean Patent Application No. 2006-71901 filed on Jul. 31, 2006, the contents of which are herein incorporated by reference in their entirety.

### BACKGROUND OF THE INVENTION

1. Field of the Invention

The present invention relates to photolithography. More particularly, the present invention relate to a method of correcting a pattern of a photomask using optical proximity correction (OPC).

2. Description of the Related Art

Generally, the manufacturing of a semiconductor device includes photolithography and etching processes which transcribe a pattern of a photomask, corresponding to a circuit pattern of the device, onto a wafer. More specifically, a target layer on the wafer is coated with a photoresist, and the photoresist is exposed to light directed through the photomask so that a virtual image of the pattern of the photomask is transferred to the layer of photoresist. The photoresist is then developed to strip away the exposed or non-exposed portions thereof and thereby pattern the layer of photoresist. The target layer is then etched using the patterned layer of photoresist as a mask, thereby forming a circuit pattern on the wafer.

However, an inherent limitation of the photolithography process, known as the optical proximity effect, and an inherent limitation of the etching process, known as the loading effect, can prevent the circuit pattern formed on the wafer from corresponding to the pattern of the photomask. Therefore, process proximity correction (PPC) techniques have been developed to obviate the problems caused by optical proximity and loading effects, and the like. Process proximity correction (PPC) refers to an analysis by which optical proximity and loading effects, etc., are predicted based on parameters of the photolithography and etching processes, and the predictions are used to correct the designed pattern of the photomask in advance in such a way that the optical proximity and loading effects, etc. are compensated for.

Optical proximity correction (OPC) is an aspect of PPC associated with the photolithography process. OPC is used to determine corrections for the designed pattern of the photomask. In this respect, OPC may be classified as model-based OPC that uses simulation of the photolithography process to determine corrections for the designed pattern of the photomask, and as rule-based OPC that uses a predetermined set of rules to correct the designed pattern of the photomask.

OPC is generally performed on a photomask taking into consideration information representative of the pattern to be formed on a target layer using the photomask. However, the fabrication of a semiconductor device involves forming various patterns on each of several stacked layers on a substrate (wafer). These patterns must be precisely aligned with each other one above the other. The degree to which the patterns formed on different layers are aligned with one another will be referred to as the overlay margin. Therefore, the overlay margin may also be taken into consideration in performing OPC. In particular, OPC is performed on the design pattern of a first photomask taking into consideration the overlay margin between a first actual pattern formed on a substrate using the first photomask and a design pattern of a second photomask used for forming another actual pattern on the substrate.

However, the line width of the design pattern of a photomask may be greater than that of the actual pattern formed on the substrate using the photomask. Also, the actual pattern formed on the substrate may be rounder than that of the design pattern. The conventional OPC method is performed taking into consideration the design pattern of the second photomask even though there may be differences, as noted above, between the design pattern and the actual pattern. As a result, the circuit pattern may incur certain types of defects.

More specifically, the design pattern of the second photomask may have a larger line width and sharper edges than those of the actual pattern formed using the second photomask. Therefore, OPC may be performed on relatively large portions of the first design pattern due to the fact that the OPC method factors in the large line width of the second design pattern. As a result, the spacing between features of the OPC, that is, the pattern of the photoresist formed using the photomask, is exceedingly narrow. Also, edges of the OPC pattern become relatively sharp. In fact, the distance between features of the OPC pattern can be reduced to such an extent that a bridge is produced in the circuit pattern formed using the OPC as an etch mask. In addition, edges of the features OPC pattern may become so sharp that a notch is generated in the edge of a feature of the circuit pattern when the OPC pattern is used as an etch mask.

### SUMMARY OF THE INVENTION

An object of the present invention is to provide a method of correcting a pattern of a photomask in such a way as to prevent bridging or notches from being produced in a pattern formed on a substrate by a photolithographic process in which the photomask is employed.

According to one aspect of the present invention, there is provided a method wherein a first pattern of a photomask designed to form a first actual pattern on a substrate in a photolithographic process is conceived, an image of a second actual pattern that is to be stacked with the first actual pattern on the substrate is obtained, and optical proximity correction (OPC) is performed on the first pattern based on information representative of the image of the second actual pattern.

Subsequently, a margin of overlay (degree of alignment) between the second actual pattern and the first corrected pattern may be characterized. The optical proximity correction is iterated with respect to the first pattern until the margin of overlay has at least one predetermined characteristic, e.g., a sufficient area and/or uniformity.

The image of the second actual pattern may be obtained by capturing an actual image of the second actual pattern, or by simulating a photolithographic process in which a pattern of a photomask, designed for forming the second actual pattern, is transcribed onto a substrate.

According to still another aspect of the invention, information correlating the first design pattern and the first actual pattern is produced. The optical proximity correction may be performed on the first design pattern based on information representative of the image of the second actual pattern and the information correlating the first design pattern and the first actual pattern. According to one example embodiment, the correlation information may be information with respect to differences between the first design pattern and the first actual pattern due to an optical proximity effect used when the first actual pattern is formed.

According to the present invention, the OPC is preformed on the pattern of a photomask, designed for forming a first actual pattern, based on information including an image of a second actual pattern stacked with the first pattern. The image of the second actual pattern is smaller and rounder shape than that of the pattern of the second photomask designed to form the second actual pattern. Therefore, region where the OPC is performed on the designed pattern of the first photomask is minimized. Accordingly, the photolithography process using the first photomask, and the etching process performed thereafter, will form a pattern on a substrate that does not include known defects such as a bridges or notches.

### BRIEF DESCRIPTION OF THE DRAWINGS

The above and other objects, features and advantages of the invention will become more readily apparent by referring to the following detailed description of the preferred embodiments thereof made in conjunction with the accompanying drawings of which:

FIG. 1 is a flow chart of a first embodiment of a method of correcting a design pattern of a mask in accordance with the present invention;

FIG. 2 is a flow chart of a second embodiment of a method of correcting a design pattern of a mask in accordance with the present invention;

FIG. 3 is a plan view of part of a pattern of a photomask corrected in accordance with the present invention as juxtaposed with the actual image of contact holes; and

FIG. 4 is a plan view of part of a photomask corrected in accordance with the prior art as juxtaposed with the designed pattern of a photomask for producing contact holes.

### DETAILED DESCRIPTION OF THE PREFERRED EMBODIMENTS

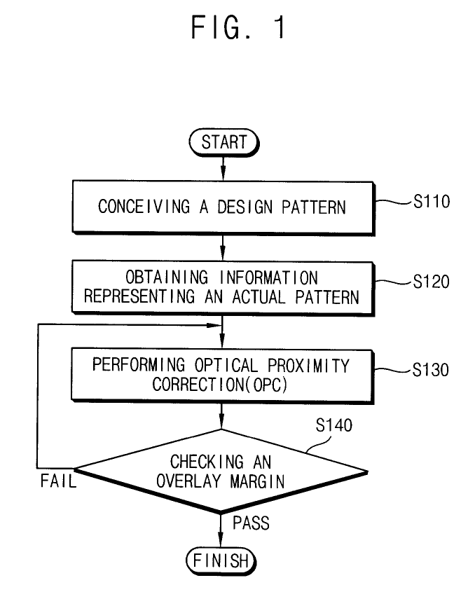

Referring to FIG. 1, first, a pattern of a first photomask for forming a first pattern on a substrate is designed (S110). The photomask is produced according to the design. Then, a first actual pattern is formed on a substrate using the photomask. That is, the (first) design pattern of the first photomask is transferred to a layer of photoresist on a target layer of the substrate using photolithography, the photoresist is developed, and the underlying target layer is etched using the developed resist as an etch mask.

In addition, information representing a second actual pattern is obtained (S120). To this end, a second photomask is produced having a second design pattern. The first and second actual patterns are patterns that are to be present at different layers in the final semiconductor device. In this embodiment, the second actual pattern is a pattern that is disposed beneath the first target layer, i.e., beneath the first actual pattern. Accordingly, the layer constituted by the first actual pattern overlies the layer constituted by the second actual pattern. Alternatively, though, the second actual pattern may be a pattern formed above the first actual pattern. Furthermore, the second actual pattern may be a pattern that is formed beneath the first actual pattern, and is repeated above the first actual pattern.

Also, in this embodiment of the present invention, the information representing the second actual pattern is acquired from an actual image of the second actual pattern formed on the substrate. In another embodiment of the present invention, the information representing the second actual pattern is acquired from a simulation of the process used to transcribe the design pattern of the second photomask onto the substrate, i.e., the information representing the second actual pattern is acquired from a simulated image of the second actual pattern. On the one hand, the information acquired from the actual image of the actual second pattern may be more accurate than that acquired from the simulated image of the second actual pattern. On the other hand, the simulated image may be more readily converted into data which can be used in the algorithm employed by the OPC process. In addition, the size of the simulated image can be readily adjusted using a relatively simple image processing program, the advantages of which will be discussed in more detail later on.

Next, an optical proximity correction (OPC) technique is performed on the first design pattern taking into account the margin of overlay between the first actual pattern and the second actual pattern (S130). As a result, a corrected pattern for the first photomask is obtained. The actual OPC technique can be model-based OPC or rule-based OPC.

In any case, the margin of overlay is based on information representing the second actual pattern, as distinguished from the prior art in which information representing the design pattern of the second photomask is used.

The second actual pattern may have a narrower line width and rounder edges than the second design pattern. Therefore, according to the present invention, the OPC may be performed on a relatively small portion of the first design pattern. Thus, the distance between features of the OPC pattern, namely the first design pattern on which the optical proximity correction has been performed, remains large enough so that bridges are not produced in the pattern of the target layer formed using a photomask, which has a pattern corresponding to the OPC pattern, as an etch mask. In addition, the edges of the OPC pattern will be fairly rounded so that notches are not produced in edges of the pattern of the target layer. Furthermore, the margin of overlay between the OPC pattern and the second actual pattern is maximized. Thus, the margin of overlay between the OPC pattern and the second actual pattern can be readily determined with a high degree of accuracy.

Moreover, the size of the simulated image of the second actual pattern may be adjusted as mentioned above. Therefore, the potential for forming bridges can be reduced, and a desired margin of overlay between the OPC pattern and the second actual pattern may be realized. For example, when the OPC is performed on the design pattern taking into account the reduced size of the simulated image of the second actual pattern, the distance between features of the OPC pattern is correspondingly increased, thereby ensuring that bridges are not produced, whereas the margin of overlay between the OPC pattern and the second actual pattern is reduced reflectively. On the other hand, when the OPC is performed on the design pattern taking into account the increased size of the simulated image of the second actual pattern, the distance between features of the OPC pattern is correspondingly reduced, thereby producing bridges, whereas the margin of overlay between the OPC pattern and the second actual pattern is increased reflectively.

Next, the margin of overlay between the second actual pattern and the corrected pattern of the first mask is delineated and characterized (S140). The corrected design pattern of the first photomask is re-corrected using an iteration of the model- or rule-based OPC algorithm, and the margin of overlay between the corrected pattern of the first photomask and the second actual pattern formed using the second photomask is checked again. The iteration (S130) is repeated until the margin of overlay has a predetermined area and uniformity. At that time, a photomask having a pattern corresponding to the most recently corrected pattern is produced for use in carrying out an actual photolithographic process.

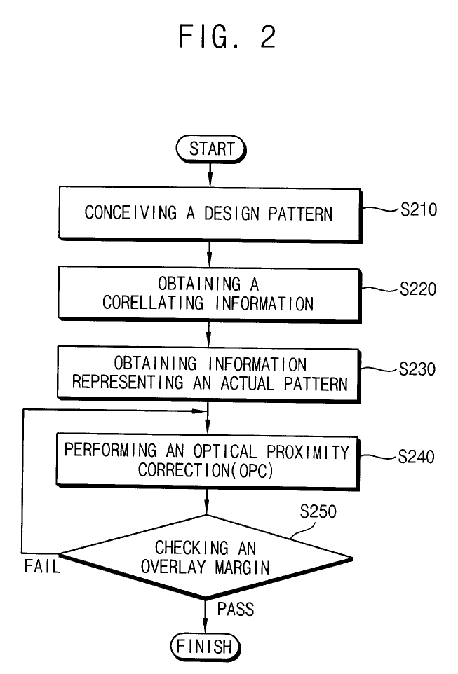

FIG. 2 is a flow chart of a second embodiment of a method of correcting a designed pattern of a mask in accordance with the present invention.

Referring to FIG. 2, first, a pattern of a photomask for forming a first pattern on a substrate is designed, and a first actual pattern is formed using the photomask (S210). This step is substantially the same as that (S110) described with reference to FIG. 1. Thus, a further description of this step is omitted here for the sake of brevity.

Next, information correlating the first designed pattern and the first actual pattern is obtained (S220). More specifically, in a photolithography process, the degree of interference of light used for patterning a layer may vary in accordance with the density of the (features of the) pattern of the photomask. Due to this optical proximity effect, the pattern of the photomask may be substantially different from the actual pattern formed on the substrate using the photomask.

In one embodiment of the present invention, the correlation between the first designed pattern and the first actual pattern may be obtained using a model of the photolithography process. The model is developed as follows. First, a photomask having several test patterns is produced. The test patterns are then transcribed onto a test substrate using photolithography. Then, the distances between features of the patterns formed on the test substrate are measured. The measurements are then used to produce a model (algorithm) that correlates photomask patterns to the actual patterns that will be produced in a photolithography process in which the optical proximity effect occurs.

In another embodiment of the present invention, the correlation between the first designed pattern and the first actual pattern may be obtained according to rules. The rules are developed as follows. First, a photomask having a test pattern is produced. The test pattern of the photomask is transcribed onto a test substrate using photolithography. Then, differences between the pattern formed on the test substrate and the pattern of the photomask are measured. The measurements are then used to develop rules correlating the geometry of photomask patterns to the patterns that will be formed on a substrate.

In addition, information representing a second actual pattern, which is stacked above and/or below the first actual pattern, is obtained (S230). This step is substantially the same as that (S120) described with reference to FIG. 1. Thus, this step will not be described further for the sake of brevity.

Next, optical proximity correction (OPC) is performed on the pattern of the first photomask taking into account the correlation information and the information representing the second actual pattern (S240). In this step, the technique for performing the OPC is substantially the same as that (S130) described with reference to FIG. 1 except that the correlation information as well as the information representing an image of the second actual pattern is used.

Next, a margin of overlay between the second actual pattern and the corrected pattern of the first mask is checked, the iteration is repeated if the margin of overlay does not have a predetermined area and uniformity, and the process is complete once the margin of overlay has a predetermined area and uniformity (S250). Again, this part of the process is substantially the same as that (S140) described with reference to FIG. 1.

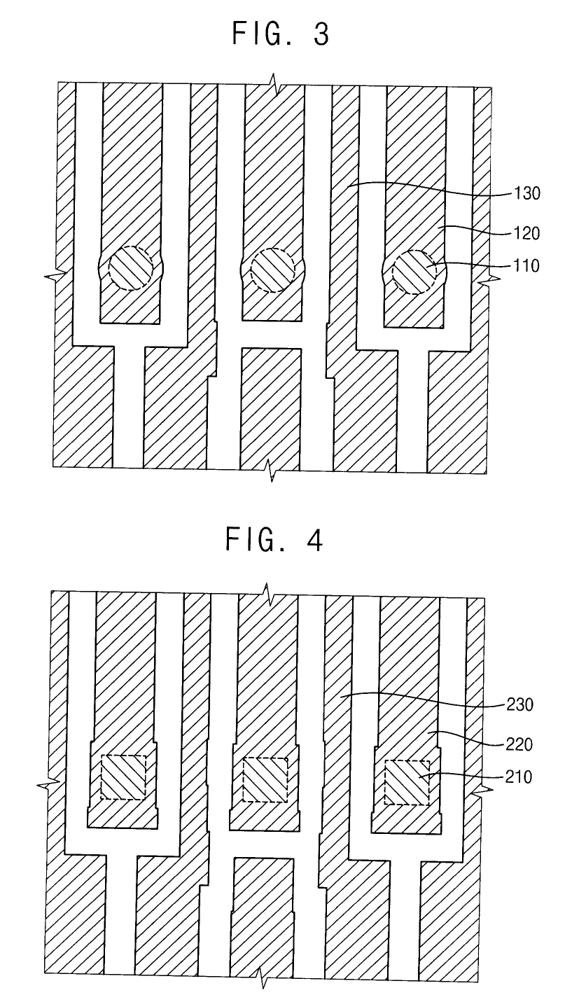

FIG. 3 is illustrates results of the OPC method in accordance with the present invention, and FIG. 4 illustrates results of an OPC method in accordance with the prior art.

Referring to FIG. 3, the OPC is performed on portions 120 and 130 of a photomask pattern for producing pads and bit lines, respectively, over circular metal contacts 110. The OPC takes into account information representing an image of the actual pattern of the metal contacts 110, which information is acquired by performing a simulation of the photolithography process used to form the holes for the metal contacts (contact holes) or by actually forming the contact holes and capturing an actual image of the contact holes. The OPC is performed on a very limited region of the photomask pattern (that provides the overlay margin) because the actual images of the contact holes are circular. That is, the region of the photomask pattern on which the OPC is performed is relatively small, so that bridges between the pads and the bit lines are not formed. In addition, the OPC pattern of the pads and the bit lines has rounded edges corresponding to the shape of the metal contacts 110, so that notches are not formed.

In contrast, referring to FIG. 4, the OPC takes into account information representing a designed tetragonal pattern 210 of the second photomask that is used to form the contact holes, not information representing the actual pattern of the pads and the bit lines formed when the image of portions 220 and 230 of pattern of the first photomask are transcribed, respectively, onto the substrate. The tetragons of the designed pattern 210 of the second photomask are much larger than the circles of the actual pattern formed using the designed pattern 210. Therefore, the OPC winds up being performed on a relatively large region of the first photomask pattern corresponding to the overlay margin. That is, the OPC increases the size of the portion of the first photomask pattern for use in forming the pads and decreases the size of the portion of the first photomask pattern for use in forming the bit lines in order to secure a margin of overlay between the metal contacts and the pads and bit lines. As a result, the OPC corrected portion of the portion 220 of the photomask pattern for use in forming the pads is relatively large, which increases the likelihood of a bridge forming between the actual pad and the actual bit line. In addition, the OPC pattern has sharp edges such that notches are formed.

According to the present invention, OPC is performed on the designed pattern of a (first) photomask taking into account an image (simulated or actual) of a (second actual) pattern formed above and/or below the actual pattern formed using the (first) photomask. The simulated or actual image of the (second actual) pattern will have a smaller and rounder shape than the designed pattern of the (second) photomask used to produce the second actual pattern. Thus, the region of the (first) photomask pattern where the OPC is performed is minimal. Accordingly, bridge and notches will not be produced in the pattern formed using the (first) photomask having the corrected pattern.

Finally, although the present invention has been described in connection with the preferred embodiments thereof, it is to be understood that the scope of the present invention is not so limited. On the contrary, various modifications of and changes to the preferred embodiments will be apparent to those of ordinary skill in the art. Thus, changes to and modifications of the preferred embodiments may fall within the true spirit and scope of the invention as defined by the appended claims.

What is claimed is:

1. A method of correcting a designed pattern of a photomask for use in a method of fabricating a semiconductor device, comprising:
conceiving a first pattern of a photomask designed to form a first actual pattern on a substrate in a photolithographic process employed in said method;
obtaining an image of a second actual pattern that is to be stacked with the first actual pattern on the substrate and is formed using another photomask in the photolithographic process; and
performing optical proximity correction (OPC) on the first pattern based on information representative of the image of the second actual pattern.

2. The method of claim 1, further comprising:
characterizing a margin of overlay in said method between the second actual pattern and the first design pattern on which the optical proximity correction has been performed; and
iterating the optical proximity correction on the first design pattern until the margin has at least one predetermined characteristic.

3. The method of claim 1, wherein the obtaining of the image of the second actual pattern comprises capturing an actual image of the second actual pattern.

4. The method of claim 1, wherein the obtaining of the image of the second actual pattern comprises simulating a transcription of the pattern of said another photomask to obtain simulated data representing the image of the second actual pattern.

5. The method of claim 4, further comprising adjusting the size of the image of the second actual pattern by processing the data, and
wherein the optical proximity correction (OPC) on the first pattern is performed based on the processed data.

6. The method of claim 1, further comprising producing information correlating the first pattern of the photomask and the first actual pattern, and
wherein the optical proximity correction on the first pattern is performed based on the information representative of the image of the second actual pattern and the information correlating the first pattern of the photomask and the first actual pattern.

7. A method of correcting a designed pattern of a photomask for use in a method of fabricating a semiconductor device, comprising:
conceiving a first pattern of a photomask designed for forming a first actual pattern on a substrate in a photolithographic process employed in said method;
producing information correlating the first pattern of the photomask and the first actual pattern;
obtaining an image of a second actual pattern that is to be stacked with the first actual pattern on the substrate and is formed using another photomask in the photolithographic process;
performing optical proximity correction (OPC) on the first pattern based on the information representative of the image of the second actual pattern and the information correlating the first pattern of the photomask and the first actual pattern;
characterizing a margin of overlay in said method between the second actual pattern and the first design pattern on which the optical proximity correction has been performed; and
iterating the optical proximity correction on the first design pattern until the overlay margin has at least one predetermined characteristic.

8. The method of claim 7, wherein the correlation information comprises information indicative of a difference between the first pattern and the first actual pattern caused by an optical proximity effect that occurs when the first actual pattern is formed.
